(19) United States
(12) Patent Application Publication
(10) Pub. No.: US 2026/0114312 A1
(43) Pub. Date: Apr. 23, 2026

(54) SEMICONDUCTOR DEVICE

(71) Applicant: UNITED MICROELECTRONICS CORP., Hsin-Chu City (TW)

(72) Inventors: Chau-Chung Hou, Tainan City (TW); Hsiang-Chi Chien, Pingtung County (TW); Hsin-Jung Liu, Pingtung County (TW)

(73) Assignee: UNITED MICROELECTRONICS CORP., Hsin-Chu City (TW)

(21) Appl. No.: 18/954,398

(22) Filed: Nov. 20, 2024

(30) Foreign Application Priority Data
Oct. 22, 2024 (TW) 113140126

(51) Int. Cl. H01L 23/00

(52) U.S. Cl. CPC H10W 72/90; H10W 72/923; H10W 72/932; H10W 72/934; H10W 72/942; H10W 72/952

(57) ABSTRACT

ABSTRACT OF DISCLOSURE A semiconductor device includes a dielectric layer, a metal wire, and a plurality of via structures. The dielectric layer is disposed on a substrate, and the metal wire is disposed within the dielectric layer. The via structures are separately disposed within the dielectric layer, on the metal wire and physically contacting the metal wire. The via structures are arranged along a first direction and a second direction being perpendicular to the first direction, at least into a 2×2 array, wherein a ratio between a total area of the via structures and an area of the metal wire is greater than 0.13.

### BACKGROUND OF THE INVENTION

### 1. Field of the Invention

The invention relates to a semiconductor device, and more particularly, to a semiconductor device having a via structure.

### 2. Description of the Prior Art

The integrated circuits (ICs) are generally related to several devices and metallic interconnecting layers commonly formed by patterned structure within a substrate or different layers. To meet the need of high integration and high processing speed of semiconductor integrated circuits of nano-scale generations, copper interconnect technology has become an effective solution. In comparison with aluminum or other metals, copper has relatively lower resistivity and fewer reliability concerns, such as electromigration, which may further cooperate with low permittivity (low-k) dielectric materials between those metal interconnects, so as to reduce cross talk and/or resistance-capacitance (RC) delay thereof. Thus, copper interconnect technology has been widely in use in single damascene structure and dual damascene structure processes. However, in the conventional arts, one concern with the use of copper as interconnect material is its diffusion property and selective corrosiveness, easily leading to structural defects. Consequently, how to improve the reliability of plugs, and to obtain the overall efficient performance of the integrated circuits are still an important issue in the field.

### SUMMARY OF THE INVENTION

It is one of the primary objectives of the present invention to provide a semiconductor device, where a ratio between the total area of upper plugs and the area of lower wires is maintained at a certain value, thereby improving the possible structural defects such as the local deeper recess easily occurred on the upper plugs.

To achieve the purpose described above, one embodiment of the present invention provides a semiconductor device including a dielectric layer, a metal wire, and a plurality of via structures. The dielectric layer is disposed on a substrate. The metal wire is disposed within the dielectric layer. The plurality of via structures is disposed within the dielectric layer, on the metal wire and directly in contact with the metal wire. The plurality of via structures is separately arranged along a first direction and a second direction being perpendicular to the first direction, at least into a 2×2 array, and a ratio between a total area of the plurality of via structures and an area of the metal wire is greater than at least 0.13.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 to FIG. 2 are schematic diagrams illustrating a semiconductor device according to a first embodiment of the present invention, in which:

FIG. 1 is a schematic top view of a semiconductor device according to the first embodiment of the present invention; and

FIG. 2 is a schematic cross-sectional view taken along a cross-line A-A′ in FIG. 1.

FIG. 3 is a schematic diagram illustrating a cross-sectional view of a semiconductor device according to a second embodiment of the present invention.

FIG. 4 is a schematic diagram illustrating the relationship between the size of via structures and the length ratio of the via structures and the metal wire in the semiconductor device according to the second embodiment of the present invention.

FIG. 5 to FIG. 6 are schematic diagrams illustrating a semiconductor device according to a third embodiment of the present invention, in which:

FIG. 5 is a schematic top view of a semiconductor device according to the third embodiment of the present invention; and

FIG. 6 is a schematic cross-sectional view taken along a cross-line A-A′ in FIG. 5.

### DETAILED DESCRIPTION

To provide a better understanding of the presented disclosure, preferred embodiments will be described in detail. The preferred embodiments of the present disclosure are illustrated in the accompanying drawings with numbered elements. In addition, the technical features in different embodiments described in the following may be replaced, recombined, or mixed with one another to constitute another embodiment without departing from the spirit of the present disclosure.

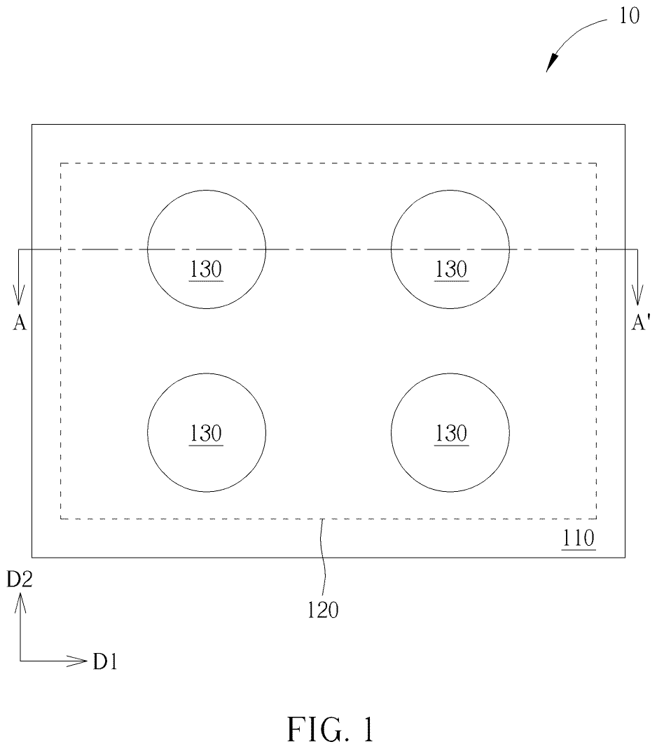

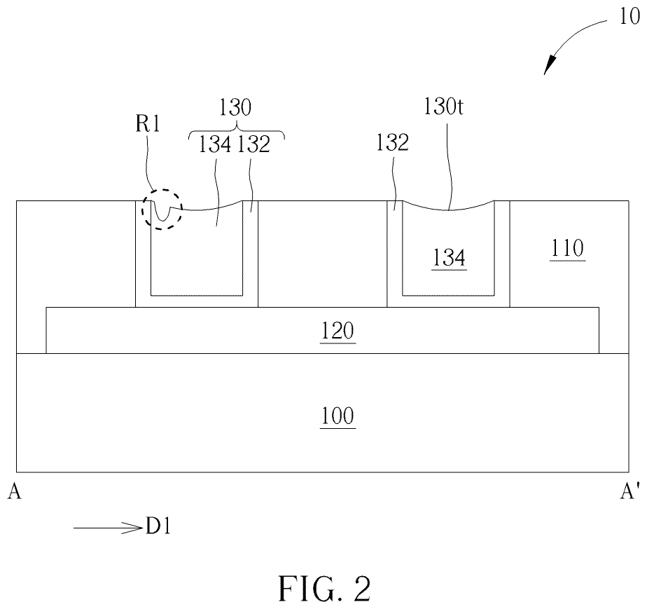

Please refer to FIG. 1 and FIG. 2, which are schematic diagrams respectively illustrating a top view and a cross-sectional view of a semiconductor device 10 according to the first embodiment of the present invention. The semiconductor device 10 includes a dielectric layer 110, a metal layer 120, and a plurality of via structures 130. The dielectric layer 110 is disposed on a substrate 100, for example being a silicon substrate, an epitaxial silicon substrate, a silicon containing substrate or a silicon-on-insulator (SOI) substrate, but not limited thereto. The metal wire 120 is disposed within the dielectric layer 110, with the metal wire 120 for example including a low-resistance metal material like copper (Cu), tungsten (W) or titanium (Ti), and preferably including copper, and with the dielectric layer 110 for example including a monolayer structure or a multilayer structure that includes a low-dielectric constant material (with the dielectric constant being lower than 3.9) like silicon oxide, silicon oxynitride (SiON), or silicon carbonitride(SiCN), but not limited thereto.

The via structures 130 are separately disposed in the dielectric layer 110, and which are disposed on the metal wire 120 in a direction (not shown in the drawings) being vertical to the substrate 100, to completely overlap the metal wire 120 underneath, and to directly contact the top surface of the metal wire 120. Precisely speaking, the via structures 130 are for example arranged along a first direction D1 and a second direction D2 which are perpendicular with each other, at least into a 2×2 array, with each of the via structures 130 further including a barrier layer 132 and a metal layer 134 stacked in sequence. The barrier layer 132 for example includes a titanium layer, a titanium nitride layer, a tantalum layer or a tantalum nitride layer, and the metal layer 134 for example includes a low-resistance metal material like copper, tungsten or titanium, and preferably includes the same metal material as that of the metal wire 120, such as copper, but not limited thereto. In one embodiment, the formation of the via structures 130 includes but is not limited to the following steps. Firstly, a plurality of through holes (not shown in the drawings) is formed in the dielectric layer 110 through a mask layer (not shown in the drawings), a barrier material layer (not shown in the drawings) and a metal material layer (not shown in the drawings) are sequentially formed partially within the through holes and partially outside the through holes, and a planarization process such as a chemical polishing process, an etching process or a combination thereof is performed, to remove the metal material layer and the barrier material layer outside the through holes, thereby forming the metal layer 134 and the barrier layer 132. Accordingly, the metal layer 134 and the barrier layer 132 within the through holes together will therefore form the via structures 130. The mask layer may be simultaneously removed through the planarization process, or, the mask layer may also be removed after forming the via structures 130. It is noted that, due to the performance of the planarization process, each of the via structures 130 includes a dishing top surface 130t, as shown in FIG. 2.

Through the arrangements of the via structures 130, the semiconductor device 10 of the present embodiment enables to be further connected to other via (not shown in the drawings) or wires (not shown in the drawings) disposed above, so that, the via structures 130, other via and other wires may therefore form the interconnection structure of the semiconductor device 10, to meet the requirements of higher integration and faster operation. However, in the embodiment in which the via structures 130 and the metal wires 120 both include copper, the Galvanic corrosion may be generated while carrying out the aforementioned planarization process, such that, a relative greater grinding and cutting effect will occur on the via structures 130 usually at the edge of a wafer. In this way, a local deeper recess R1 is easily generated on the via structures 130 disposed at the edge of a wafer.

People well known in the arts should easily realize the semiconductor device in the present disclosure is not limited to the aforementioned embodiment, and may further include other examples or variety. The following description will detail the different embodiments of the semiconductor device in the present disclosure. To simplify the description, the following description will detail the dissimilarities among the different embodiments and the identical features will not be redundantly described. In order to compare the differences between the embodiments easily, the identical components in each of the following embodiments are marked with identical symbols.

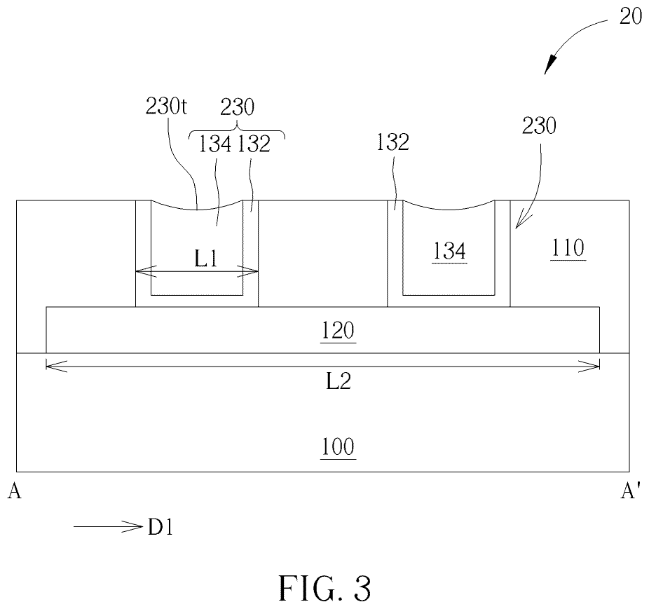

According to the second embodiment of the present invention, another semiconductor device 20 is provided for effectively improving the structural defects of the via structures 130 caused by the Galvanic corrosion, and the metal layer 134 of the via structures 130 will therefore obtain better flatness on the surface thereof. Please refer to FIG. 3, which is a schematic diagram illustrating a cross-sectional view of the semiconductor device 20 according to the second embodiment of the present invention. The structure of the semiconductor device 20 in present embodiment is substantially the same as that of the semiconductor device 10 in the aforementioned first embodiment, and all the similarities will not be redundantly described herein after. The difference between the semiconductor device 20 of present embodiment and the semiconductor device 10 of the aforementioned first embodiment is in that the ratio between a total area of the via structures 230 at the upper layer and the total area of the metal wire 120 at the lower layer is controlled above a certain value.

It is noted that, as shown in FIG. 3, each of the via structures 230 includes a length L1, and the metal wire 120 includes a length L2 in the first direction D1, and a ratio between a total area of the via structures 230 and an area of the metal wire 120 is greater than 0.13. Through these arrangements, the formation of the via structures 230 at the upper layer may be free from the influence of the Galvanic corrosion, so that, the top surface 230t of each of the via structures 230 will present in a flatter, regular shape, without generating any local deeper recess. The top surface 230t is slightly recessed from the metal layer 134 of each of the via structures 230, with the topmost point of the top surface 230t being leveled with the top surface of the barrier layer 132 of each of the via structures 230, or being leveled with the top surface of the dielectric layer 110.

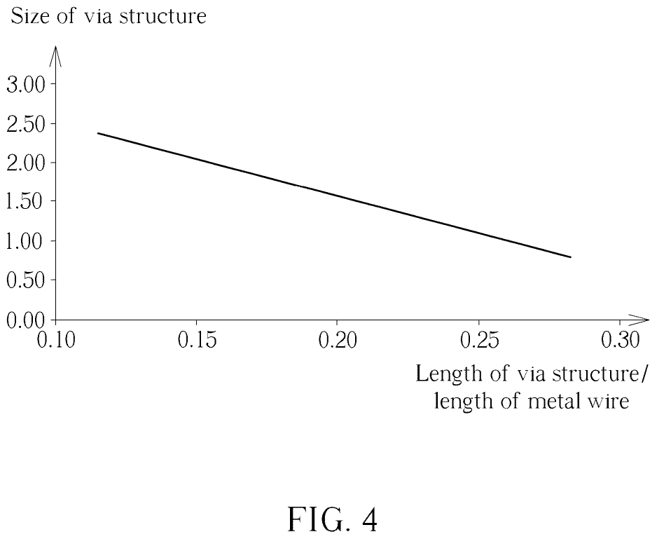

As shown in FIG. 4, in one embodiment, a ratio between the total length of all of the via structures 230 (each has the length L1 in the first direction D1) and the length L2 of the metal wire 120 may also be controlled above a certain value, for example being greater than at least 0.15, such that, the formation of the via structures 230 at the upper layer will also be free from the influence of the Galvanic corrosion. In other words, if the metal wire 120 has a square-shaped structure, the ratio between the length L1 of all of the via structures 230 and the length L2 of the metal wire 120 is greater than at least 0.15, and if the metal wire 120 has a rectangular structure, the ratio of the length L1 of all of the via structures 230 and a length (the length L2) of a corresponding side of the metal wire 120 is greater than at least 0.15, but not limited thereto. Otherwise, in another embodiment, a ratio between the length L1 of each of the via structures 230 and the length L2 of the metal wire 120 may also be controlled at a value being greater than at least 0.05 to 0.07, such that, the formation of the via structures 230 at the upper layer will also be free from the influence of the Galvanic corrosion.

According to the semiconductor device 20 of the present embodiment, the ratio between the total area of the via structures 230 and the area of the metal wire 120 is maintained above 0.13 and/or the ratio between the total length of all of the via structure 230s and the length L2 of the metal wire 120 is maintained above 0.15, by reducing the area of the metal wire 120 and/or expanding the area of the via structures 230. Thus, through well-controlling the area ratio and/or the length ratio between the via structures 230 at the upper layer and the metal wire 120 at the lower layer, the local deeper recess easily occurred on the meal layer 134 due to the Galvanic corrosion will be effectively improved, and the semiconductor device 20 will therefore gain the via structures 230 with better flatness to overall enhance the function and performance thereof.

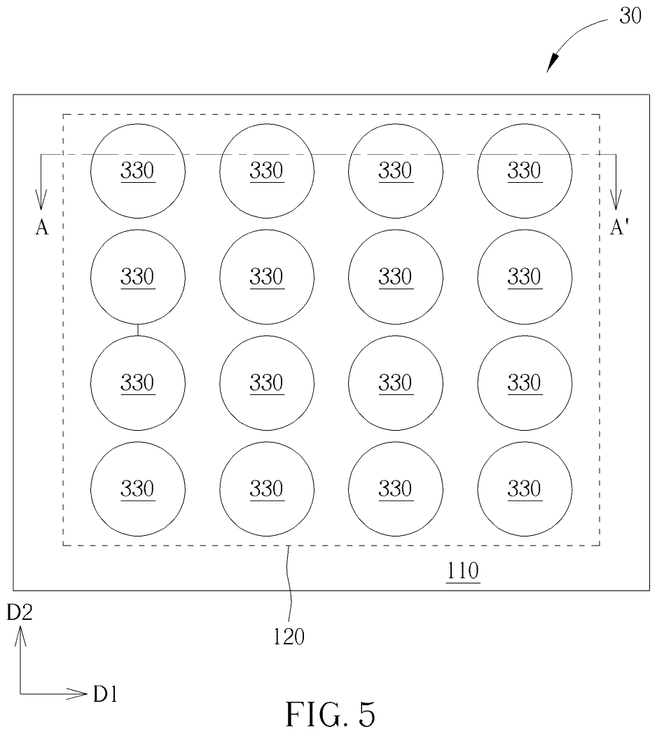

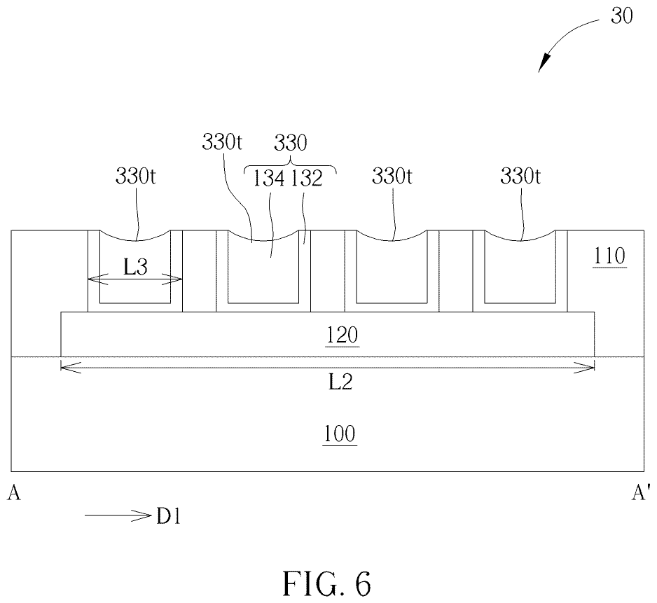

Please refer to FIG. 5 and FIG. 6, which are schematic diagrams illustrating a semiconductor device 30 according to the third embodiment of the present invention. The structure of the semiconductor device 30 in present embodiment is substantially the same as that of the semiconductor device 10 in the aforementioned first embodiment, and all the similarities will not be redundantly described herein after. The difference between the semiconductor device 30 of present embodiment and the semiconductor device 10 of the aforementioned first embodiment is in that a plurality of via structures 330 of the present embodiment is sequentially arranged along the first direction D1 and the second direction D2 into a 4×4 array.

Precisely speaking, each of the via structures 330 for example includes a length L3 in the first direction D3, and a ratio between the total area of the via structures 330 and the area of the metal wire 120 is at least greater than 0.13. Through these arrangements, the metal layer 134 of the via structures 330 at the upper layer is also free from generating the deeper recess, so that, each of the via structures 330 enables to obtain the top surface 330t in a flatter, regular shape, as shown in FIG. 6. The top surface 330t is slightly recessed from the metal layer 134 of each of the via structures 330, with the topmost point of the top surface 330t being leveled with the top surface of the barrier layer 132 of each of the via structures 330, or being leveled with the top surface of the dielectric layer 110.

In addition, a ratio between the total length of all of the via structures 330 (each has the length L3 in the first direction D1) and the length L2 of the metal wire 120 may be controlled above a certain value, for example being greater than at least 0.15, or a ratio between the length L3 of each of the via structures 330 and the length L2 of the metal wire 120 may also be controlled above a certain value, for example being greater than at least 0.05 to 0.07, such that, the metal layer 134 of the via structures 330 will also enable to be free from generating the local deeper recess.

Overall speaking, according to the semiconductor device of the present invention, the area ratio or the length ratio between the upper via and the lower wire is maintained at a certain value, by shrinking the area of the lower wire and/or expanding the area of the upper via, so as to effectively avoid the structural defects caused by Galvanic corrosion occurred on the upper via. Also, people skilled in the art should fully realize the controlled value of the area ratio or the length ratio between the upper via and the lower wire may also be applied on various semiconductor structures or various semiconductor devices. While the size, the number or the via, and the area of the wire are all diverse, through controlling the area ratio or the length ratio therebetween at the certain value, to improve the structural reliability of any semiconductor structure or semiconductor device, and to gain a better performance thereby. For example, although the via structures arranged in a 2×2 array, or a 4×4 array are exemplified in the aforementioned embodiment, the practical arrangement of the via structures in present invention is not limited thereto, and which may also be arranged into other layout like a 3×3 array, a 5×5 array, a 6×6 array, a 2×3 array, 2×4 array, 2×4 array, or 2×4 array based on device requirements. Also, the via structures in above-mentioned array will also be free from the possible defects caused by the Galvanic corrosion, by maintaining the area ratio or the length ratio between the via structures and the wire underneath at a certain value.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor device, comprising:
a dielectric layer disposed on a substrate;
a metal wire disposed within the dielectric layer; and
a plurality of via structures disposed within the dielectric layer, the plurality of via structures disposed on the metal wire and directly in contact with the metal wire, wherein the plurality of via structures is separately arranged along a first direction and a second direction being perpendicular to the first direction, at least into a 2×2 array, and a ratio between a total area of the plurality of via structures and an area of the metal wire is greater than 0.13.

2. The semiconductor device according to claim 1, wherein a ratio between a total length of the plurality of via structures and a length of the metal wire in the first direction is greater than 0.15.

3. The semiconductor device according to claim 1, wherein a ratio between a length of each of the plurality of via structures in the first direction and a length of the metal wire is greater than 0.05 to 0.07.

4. The semiconductor device according to claim 1, wherein each of the plurality of via structures completely overlaps the metal wire in a direction being vertical to the substrate.

5. The semiconductor device according to claim 1, wherein each of the plurality of via structures further comprises a barrier layer and a metal layer disposed in sequence.

6. The semiconductor device according to claim 5, wherein the metal layer and the metal wire comprise a same metal material.

7. The semiconductor device according to claim 5, wherein the metal layer comprises copper.

8. The semiconductor device according to claim 1, wherein the plurality of the via structures is arranged into a 4×4 array.

9. The semiconductor device according to claim 1, wherein the plurality of the via structures is arranged into a 3×3 array.

10. The semiconductor device according to claim 1, wherein the plurality of the via structures is arranged into a 2×3 array.

11. The semiconductor device according to claim 1, wherein the plurality of the via structures is arranged into a 2×4 array.
